(19) United States
(12) Patent Application Publication
(10) Pub. No.: US 2006/0278612 A1
(43) Pub. Date: Dec. 14, 2006

(54) Manufacturing method of semiconductor integrated circuit device

(76) Inventors: Kenji Tokunaga, Tokyo (JP); Kazuhiko Kawai, Tokyo (JP); Sakae Terakado, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/448,032

(22) Filed: Jun. 7, 2006

(30) Foreign Application Priority Data
Jun. 9, 2005 (JP) 2005-168957

(51) Int. Cl. C03C 25/68; B44C 1/22; C23F 1/00; H01L 21/302

(52) U.S. Cl. 216/67; 216/58; 438/706

(57) ABSTRACT

To provide a semiconductor integrated circuit device having improved reliability. An EFEM unit upstream of a plasma processing unit is equipped with a chemical filer for alkali removal. In the plasma processing unit, a semiconductor wafer is subjected to plasma processing with a gas containing fluorine. The resulting semiconductor wafer is put in a carrier via a transfer chamber, load lock chamber and EFEM chamber. During this operation, the concentration of amines in the EFEM chamber is adjusted to be lower than that of amines in a clean room outside the chamber by a chemical filter.

### CROSS-REFERENCE TO RELATED APPLICATION

The present application claims priority from Japanese patent application No. 2005-168957 filed on June 9, 2005, the content of which is hereby incorporated by reference into this application.

### BACKGROUND OF THE INVENTION

The present invention relates to a manufacturing technology of a semiconductor integrated circuit device, in particular, to a technology effective when applied to a plasma processing technology using a gas containing fluorine (F).

The plasma processing investigated by the present inventors is, for example, plasma etching using a fluorine-containing gas. Upstream of an etching apparatus to be used for this etching, EFEM (Equipment Front End Module) is placed. This EFEM is equipped with a load port on the front side thereof and an EFEM chamber downstream of the load port. The EFEM chamber is a module unit equipped with FFU (Fan Filter Unit) for maintaining cleanness inside of the EFEM chamber and a transfer robot contributing to the transfer of semiconductor wafers.

Semiconductor wafers etched in a plasma processing chamber of the etching apparatus are put in a carrier placed on the load port of the EFEM by means of the transfer robot in the EFEM chamber upstream of the etching apparatus. This carrier is, through a transport route, placed on the load port of the EFEM placed upstream of a manufacturing apparatus used for a subsequent manufacturing step. The semiconductor,wafers in this carrier are put in a processing chamber of the manufacturing apparatus used for a subsequent manufacturing step via the transfer robot in the EFEM chamber.

For example, in the paragraph 0029, paragraph 0039 and FIG. 1 of Japanese Unexamined Patent Publication No. Hei 10(1998)-214775, disclosed is an apparatus to be used in a lithography step with a chemically amplified resist, which apparatus has an air control unit equipped with an ammonia-removing filter in order to avoid development failure, which will otherwise be caused by an ammonia component in the process atmosphere in the process using the chemically amplified resist.

For example, in the paragraph 0075 and FIG. 11 of Japanese Unexamined Patent Publication No. 2001-143985, disclosed is a resist application/development apparatus having a temperature humidity controller equipped, in a supply line of a heat exchanger of the controller, with an ammonia removing filter.

For example, in the paragraph 0025 and FIG. 1 of Japanese Unexamined Patent Publication No. 2002-100598, disclosed is a cleaning apparatus equipped with a chemical filter.

For example, in the paragraph 0023 and FIG. 1 of Japanese Unexamined Patent Publication No. Hei 11(1999)-125914, disclosed is an apparatus to be used photolithography with a chemically amplified resist, wherein the apparatus has a wafer stocker unit equipped with a chemical filter.

### SUMMARY OF THE INVENTION

The present inventors however found for the first time that the above-described technology investigated by the present inventors has the following problem in the transition from the plasma processing using a gas containing fluorine (F) to a manufacturing step subsequent thereto.

Described specifically, the FFU of the EFEM upstream of the etching apparatus investigated by the present inventors is not equipped with a chemical filter so that amines such as ammonia (NH₃) enter from a clean room into the EFEM chamber or carrier. As a result, reaction between fluorine (F) adsorbed to the surface of the semiconductor wafer by plasma processing using a fluorine (F)-containing gas and amines contained in the EFEM chamber or carrier occurs to form a salt such as ammonium fluoride (NH₄F), leading to the problem that the salt acts as an etching mask in the subsequent manufacturing step or acts as a cause for generating voids. In particular, when a closed type carrier such as FOUP (Front-Opening Unified Pod) is used as the carrier, fluorine is apt to remain on the surface of the semiconductor wafer or in the carrier and form the salt. The above-described problem therefore becomes prominent, resulting in deterioration in the reliability and production yield of the semiconductor integrated circuit device.

An object of the present invention is therefore to provide a technology capable of manufacturing a semiconductor integrated circuit device having improved reliability.

The above-described and the other objects, and novel features of the present invention will be apparent from the description herein and accompanying drawings.

Of the inventions disclosed by the present application, typical ones will next be outlined briefly.

In the present invention, when wafers are subjected to plasma processing with a fluorine-containing gas by using a plasma processing unit, a chemical filter is attached to a module unit disposed upstream of the plasma processing unit so as to make the amount of alkali contaminants inside of the module unit smaller than that outside the module unit in the steps after the plasma processing.

In the present invention, when wafers are subjected to plasma processing with a fluorine-containing gas by using a plurality of plasma processing units different from each other, a chemical filter is attached to at least one module unit disposed upstream of the plurality of plasma processing units so as to make the amount of alkali contaminants in at least one of the module unit smaller than that outside the module unit in the steps after the plasma processing.

In the present invention, when wafers are subjected to plasma etching with a fluorine-containing gas by using a plurality of plasma etching units different from each other, a chemical filter is attached to at least one module unit disposed upstream of the different plasma etching units so as to make the amount of alkali contaminants in at least one of the module unit smaller than that outside the module unit in the steps after the plasma etching.

Of the inventions disclosed by the present application, advantages attained by typical inventions will next be described briefly.

Described specifically, a reaction between fluorine adsorbed to the surface of a wafer which has finished plasma processing and an alkali contaminant inside of a module unit can be suppressed and therefore the amount of a salt which will otherwise be formed by the reaction can be reduced. It is therefore possible to suppress or prevent the phenomenon that the salt acts as an etching mask or becomes a cause for generation of voids in the steps after plasma processing. This leads to improvement in the reliability of a semiconductor integrated circuit device.

### BRIEF DESCRIPTION OF THE DRAWINGS

FIG. 1 is a schematic view illustrating an example of the cross section structure of a plasma processing system investigated by the present inventors.

FIG. 2 is a schematic view illustrating an example of the planar structure of the plasma processing system of FIG. 1.

FIG. 3 is a schematic view illustrating plasma processing using two plasma processing systems having the structures as illustrated in FIGS. 1 and 2.

FIG. 4 is a fragmentary cross-sectional view of a semiconductor wafer during a manufacturing step of a semiconductor integrated circuit device, for explaining the problem found by the present inventors.

FIG. 5 is a fragmentary cross-sectional view of a semiconductor wafer during a manufacturing step of the semiconductor integrated circuit device following the step of FIG. 4.

FIG. 6 is a fragmentary cross-sectional view of a semiconductor wafer during a manufacturing step of the semiconductor integrated circuit device following the step of FIG. 5.

FIG. 7 is a fragmentary cross-sectional view of a semiconductor wafer during a manufacturing step of the semiconductor integrated circuit device following the step of FIG. 6.

FIG. 8 is a fragmentary cross-sectional view of a semiconductor wafer during a manufacturing step of a. semiconductor integrated circuit device, for explaining another problem found by the present inventors.

FIG. 9 is a fragmentary cross-sectional view of a semiconductor wafer during a manufacturing step of the semiconductor integrated circuit device following the step of FIG. 8.

FIG. 10 is a fragmentary cross-sectional view of a semiconductor wafer during a manufacturing step of the semiconductor integrated circuit device following the step of FIG. 9.

FIG. 11 is a fragmentary cross-sectional view of a semiconductor wafer during a manufacturing step of the semiconductor integrated circuit device following the step of FIG. 10.

FIG. 12 is a fragmentary perspective view of an example of an intrabay transport portion of a semiconductor manufacture line to be used for the manufacture of a semiconductor integrated circuit device according to one embodiment of the present invention.

FIG. 13 is a perspective view illustrating an example of a carrier to be used in the manufacturing step of a semiconductor integrated circuit device according to one embodiment of the present invention.

FIG. 14 is a schematic view illustrating the structure of a plasma processing system, which is a part of the manufacturing apparatus illustrated in FIG. 12.

FIG. 15 is a schematic view illustrating plasma processing using two plasma processing systems having the structures as illustrated in FIGS. 14 and 2.

FIG. 16 is a graph showing an example of the effect brought by the installment of a chemical filter.

FIG. 17 is a fragmentary cross-sectional view of a semiconductor wafer during a manufacturing step of a semiconductor integrated circuit device according to one embodiment of the present invention.

FIG. 18 is a fragmentary cross-sectional view of a semiconductor wafer during a manufacturing step of the semiconductor integrated circuit device following the step of FIG. 17.

FIG. 19 is a fragmentary cross-sectional view of a semiconductor wafer during a manufacturing step of the semiconductor integrated circuit device following the step of FIG. 18.

FIG. 20 is a fragmentary cross-sectional view of a semiconductor wafer during a manufacturing step of the semiconductor integrated circuit device following the step of FIG. 19.

FIG. 21 is a fragmentary cross-sectional view of a semiconductor wafer during a manufacturing step of the semiconductor integrated circuit device following the step of FIG. 20.

FIG. 22 is a fragmentary cross-sectional view of a semiconductor wafer during a manufacturing step of the semiconductor integrated circuit device following the step of FIG. 21.

FIG. 23 is a fragmentary cross-sectional view of a semiconductor wafer during a manufacturing step of the semiconductor integrated circuit device following the step of FIG. 22.

FIG. 24 is a fragmentary cross-sectional view of a semiconductor wafer during a manufacturing step of the semiconductor integrated circuit device following the step of FIG. 23.

FIG. 25 is a fragmentary cross-sectional view of a semiconductor wafer during a manufacturing step of the. semiconductor integrated circuit device following the step of FIG. 24.

FIG. 26 is a fragmentary cross-sectional view of a semiconductor wafer during a manufacturing step of the semiconductor integrated circuit device following the step of FIG. 25.

### DETAILED DESCRIPTION OF THE PREFERRED EMBODIMENTS

Prior to detailed description of the embodiment of the present invention, meanings of the terms used in the embodiment will next be explained.

1. The term “wafer” means a single crystal silicon substrate (semiconductor wafer: usually having a substantially circular and flat), a sapphire substrate, a glass substrate, or any other insulating, semi-insulating or semiconductor substrate, or a composite substrate thereof which is used for the fabrication of integrated circuits.

2. The term “semiconductor integrated circuit device” as used herein means not only those fabricated over a semiconductor or insulator substrate such as silicon wafer or sapphire substrate but also those formed over other insulating substrates such as glass substrates, e.g., TFT (Thin Film Transistor) and STN (Super Twisted Nematic) liquid crystals, unless otherwise specifically indicated.

3. The term “device surface” means a main surface of a wafer over which device patterns corresponding to plural chip regions are to be formed by lithography.

4. The term “etching gas” means a reaction gas, a dilution gas or the other gas. The reaction gas can be classified into a main reaction gas and addition reaction gas. The main reaction gas to be used for etching of an insulating film or polycrystalline silicon film is, for example, a fluorocarbon gas, while the addition reaction gas is, for example, a gas containing oxygen (O₂) The fluorocarbon gas can be classified into a saturated gas and unsaturated gas.

In the below-described embodiments, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated. In the below-described embodiments, when a reference is made to the number of elements (including the number, value, amount and range), the number is not limited to a specific number but can be greater than or less than the specific number unless otherwise specifically indicated or principally apparent that the number is limited to the specific number. Moreover in the below-described embodiments, it is needless to say that the constituting elements (including element steps) are not always essential unless otherwise specifically indicated or principally apparent that they are essential. Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range. In all the drawings for describing the embodiments, like members of a function will be identified by like reference numerals and overlapping descriptions will be omitted as much as possible. Embodiments of the present invention will next be described specifically based on drawings.

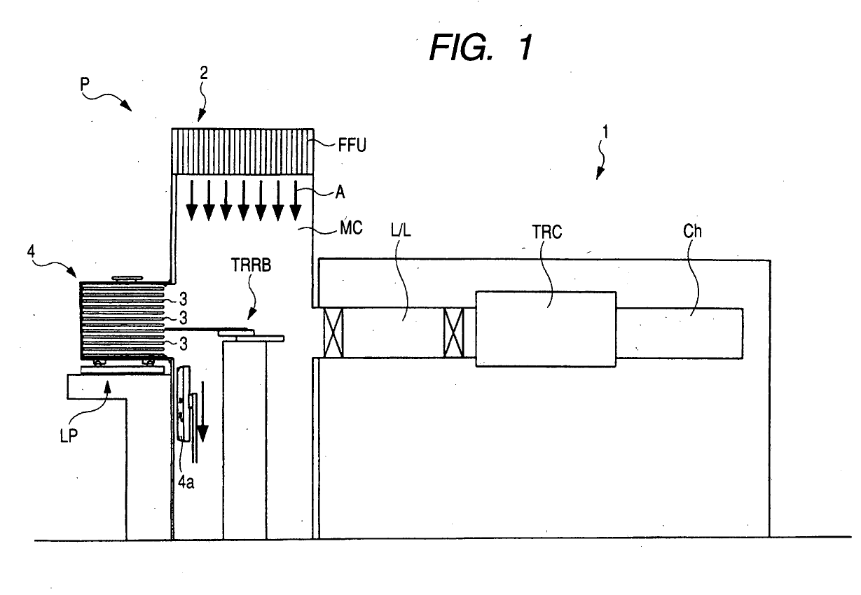

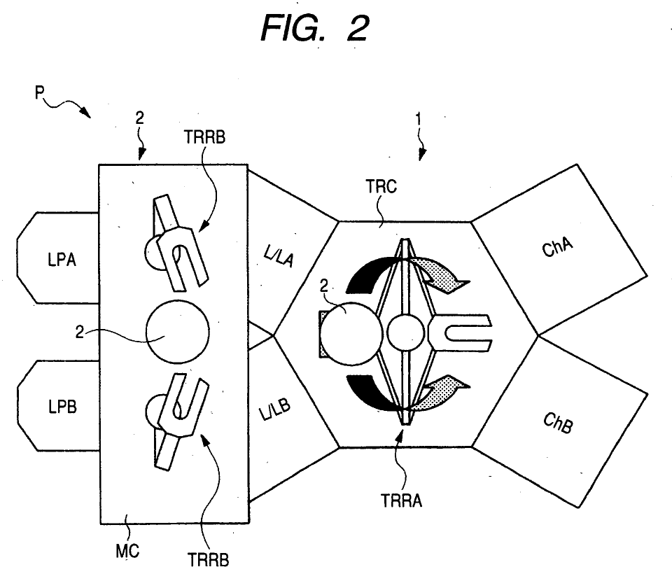

FIGS. 1 and 2 illustrate one example of the structure of a plasma processing system P investigated by the present inventors. FIG. 1 is a schematic view illustrating an example of the cross section structure of the plasma processing system P, while FIG. 2 is a schematic view illustrating an example of the planar structure of the plasma processing system P of FIG. 1.

The plasma processing system P has a plasma processing unit 1 and EFEM (Equipment Front End Module) unit 2. The plasma processing unit 1 has a load lock chamber (vacuum spare chamber), L/L (L/LA, L/LB), transport chamber TRC and process chamber Ch (ChA, ChB).

The load lock chamber L/L is a vacuum chamber for inserting and retrieving a semiconductor wafer 3 without exposing the process chamber Ch to the atmosphere. This load lock chamber L/L is disposed upstream of the transport chamber TRC via a valve. The vacuum condition inside the process chamber Ch can be maintained by using the valve and vacuum evacuation operation in combination.

Downstream of the load lock chamber L/L, the transport chamber TRC is disposed. This transport chamber TRC has a transfer robot TRRA therein. The semiconductor wafer 3 is transferred between the load lock chamber L/L and process chamber Ch by the transfer robot TRRA.

Downstream of the transport chamber TRC, the process chamber Ch is disposed. This process chamber Ch is a chamber in which plasma processing is carried out. In this process chamber Ch, plasma etching using, as a main reaction gas, a gas containing fluorine (F) such as fluorocarbon gas or ashing mainly for the removal of organic foreign matters such as resist is performed.

Upstream of this plasma processing unit 1, the EFEM unit 2 is disposed. The EFEM unit 2 is also called enclosure and it serves as a portion for forming a closed space for isolating the semiconductor wafer 3 from a contamination source, thereby forming a clean environment. The EFEM unit 2 is a module unit having a load port LP (LPA, LPB) installed on the front side thereof, the EFEM chamber (mini-environment) MC downstream of the load port LP, a fan filter unit FFU and a transfer robot (TRRB).

The load port LP is an interface portion for supplying the semiconductor wafer 3 to the plasma processing unit 1. The load port LP has a role of receiving a carrier 4 from a host computer or the like, feeding the semiconductor wafer 3 into the plasma processing unit 1, housing the semiconductor wafer 3 which has finished the plasma processing in the carrier 4 and sending it to a transport system. The load port LP has a function of clamping, docking and undocking the carrier 4 and a function of opening/closing a carrier door 4a. The load port LP sometimes has a function of mapping the semiconductor wafer 3 in the carrier 4. The load port LP is highly standardized by SEMI and has mechanical compatibility with a carrier or load port of another company.

The fan filter unit FFU is an air cleaning unit having, for example, integrated combination of an ULPA (Ultra Low Penetration Air) filter and a small-sized fan. It has a function of removing dust particles in the air. Since the carrier door 4a of the carrier 4 is opened only in the EFEM chamber MC and the fan filter unit FFU is installed, the cleanliness in the EFEM chamber MC is kept at, for example, class 1 relative to the cleanliness class 100 of the clean room outside the EFEM chamber MC. The ULPA filter is an air filter having a trapping ratio of particles having a particle size of 0.15 μm as high as 99.9995% or greater at a rated air volume and at the same time, having usually an initial pressure loss not greater than 300 Pa or less.

This fan filter unit FFU is however not equipped with a chemical filter for alkali removal so that the concentration of amines such as ammonia (NH₃) in the EFEM chamber MC is, for example, about 5 to 20 μg/m³, which is the same level or almost the same level as that of the amines in the clean room outside the EFEM chamber MC.

The term “cleanliness class” means the cleanliness of a space classified using, as an index, the number of dust particles having a particle size of about 0.1 μm or greater contained in the air of 1 ft³ (1 ft=30.48 cm). In cleanliness class 1, the number of dust particles having a particle size of 0.1 μm or greater contained in the air of 1 ft³ is 1 or less, while in cleanliness class 1000, the number of dust particles having a particle size of 0.1 μm or greater contained in the air of 1 ft³ is 1000 or less. Arrows A in FIG. 1 indicate the air flow from the clean room outside the EFEM chamber MC to the inside of the EFEM chamber MC via the fan filter unit FFU.

The transfer robot TRRB is a robot contributing to the transfer of the semiconductor wafer 3, for example, it retrieves the semiconductor wafer 3 in the carrier 4 and carries it in the load lock chamber L/L, or it retrieves the semiconductor wafer 3 from the load lock chamber L/L and carries it in the carrier 4.

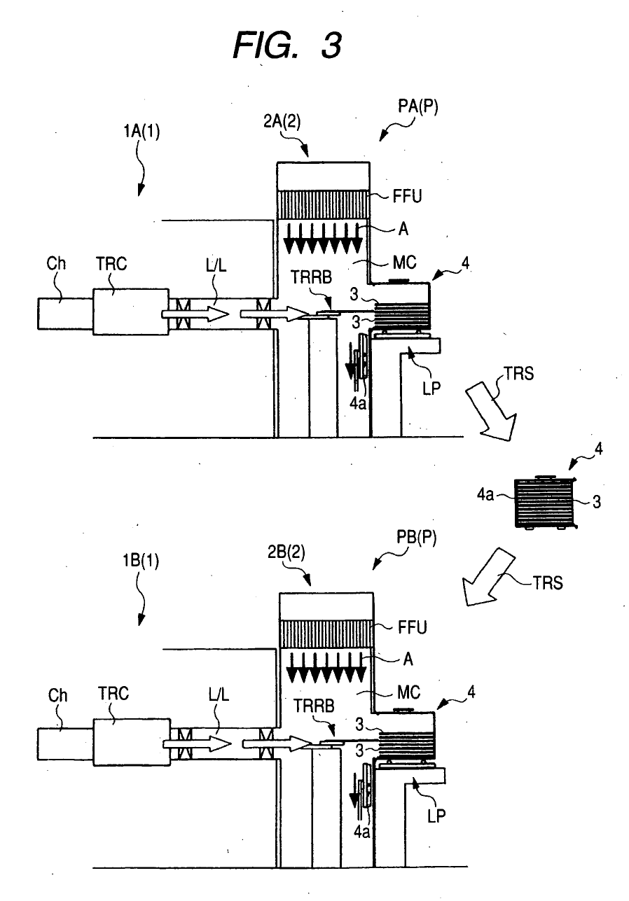

FIG. 3 illustrates one example of plasma processing performed in two plasma processing systems PA and PB (P) having the structure as illustrated in FIGS. 1 and 2.

The semiconductor wafer 3 subjected to plasma processing in the process chamber Ch of a plasma processing unit 1A (1) of a plasma processing system PA illustrated in the upper diagram of FIG. 3 is put in a carrier 4 placed on a load port LP of an EFEM unit 2A via an EFEM chamber MC of the EFEM unit 2A (2) upstream of the plasma processing unit 1A. The carrier 4 is, via a transport system TRS, placed on a load port LP of an EFEM unit 2B (2) of a plasma processing system PB illustrated in the lower diagram of FIG. 3. The semiconductor wafer 3 in the carrier 4 is put in a process chamber Ch of a plasma processing unit 1B (1) via an EFEM chamber MC of the EFEM unit 2B. The semiconductor wafer 3 is then subjected to desired plasma processing in the process chamber Ch of the plasma processing unit 1B.

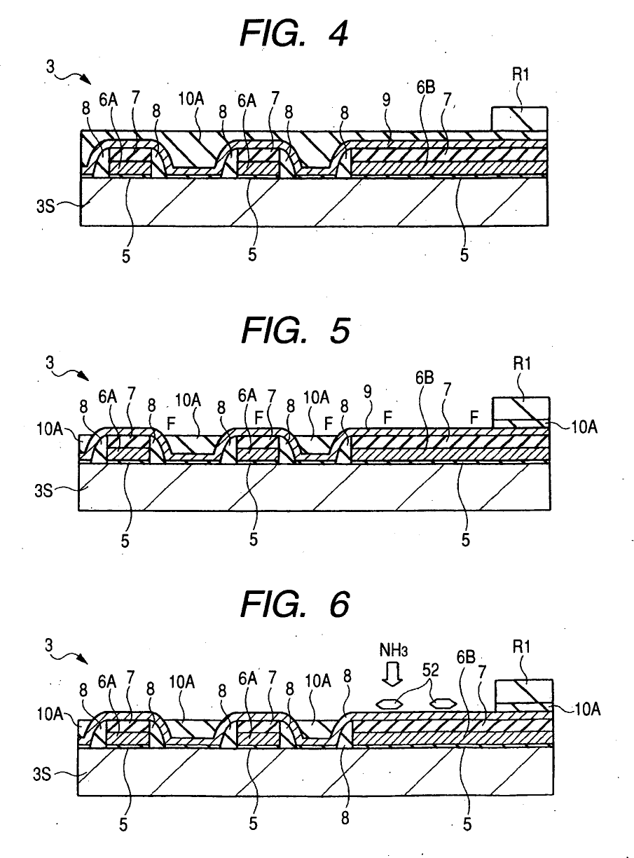

The present inventors have however found for the first time that the plasma processing system P and plasma processing step as described above have the following problem. The problem will next be described with reference to FIGS. 4 to 7 and FIGS. 8 to 11.

FIGS. 4 to 7 are fragmentary cross-sectional views of the semiconductor wafer 3 during the manufacturing steps of a semiconductor integrated circuit device having, for example, an AG-AND type flash memory of 1 GB.

FIG. 4 is a fragmentary cross-sectional view of the semiconductor wafer 3 prior to plasma etching. A semiconductor substrate (which will hereinafter be called “substrate” simply) 3S of the semiconductor wafer 3 is made of, for example, p type silicon (Si) single crystal. This substrate 3S has, over the main surface (device surface) in a memory region thereof, an auxiliary gate electrode 6A formed via a gate insulating film 5. Over the main surface (device surface) in a peripheral region of the substrate 3S, a conductor pattern 6B is formed via the gate insulating film 5. The auxiliary gate electrode 6A and conductor pattern 6B are each made of, for example, low resistance polycrystalline silicon. Over the auxiliary gate electrode 6A and conductor pattern 6B, a cap insulating film 7 is formed. On the side surfaces of the auxiliary gate electrode 6A and conductor pattern 6B, sidewalls 8 are formed. Over the main surface of the substrate 3S, a conductor film 9 for the formation of a floating gate electrode is deposited to cover therewith the cap insulating film 7 and sidewalls 8. The conductor film 9 is made of, for example, low resistance polycrystalline silicon. Over the conductor film 9, an antireflective film 10A is deposited and thereover, a resist pattern R1 is formed.

The semiconductor wafer 3 of FIG. 4 is put in the process chamber Ch of the plasma processing unit 1A of FIG. 3 and the antireflective film 10A over the main surface of the semiconductor wafer 3 is plasma-etched, for example, with a mixed gas of carbon tetrafluoride (CF₄), oxygen (O₂) and argon (Ar). FIG. 5 is a fragmentary cross-sectional view of the semiconductor wafer 4 which has finished the plasma etching. The antireflective film 10 remains in a space between two adjacent auxiliary gate electrodes 6A and under the resist pattern R1. In this stage, fluorine (F) is adsorbed onto the surface of the semiconductor wafer 3.

The semiconductor wafer 3 which has finished plasma etching in the plasma processing unit 1A is carried out of the load lock chamber L/L of the plasma processing unit 1A and carried in the load lock chamber L/L of the plasma processing unit 1B illustrated in the lower diagram of FIG. 3. FIG. 6 is a fragmentary cross-sectional view of the semiconductor wafer 3 during its transport from the load lock chamber L/L of the plasma processing unit 1A to the load lock chamber L/L of the plasma processing unit 1B. At this time, since the fan filter unit FFU of the EFEM units 2A,2B upstream of the plasma processing units 1A, 1B investigated by the present inventors is not equipped with a chemical filter, amines such as ammonia (NH₃) in the clean room enters inside of the EFEM chamber MC or inside of the carrier 4. As a result, fluorine (F) adsorbed onto the surface of the semiconductor wafer 3 by the plasma etching reacts with amines contained in the EFEM chamber MC or carrier 4 to form a salt 52 such as ammonium fluoride (NH₄F). In particular, use of a closed type carrier 4 such as FOUP (Front-Opening Unified Pod) as the carrier 4 facilitates remaining of fluorine on the surface of the semiconductor wafer 3 or in the carrier 4, whereby the salt 52 is formed easily and the problem as described below becomes prominent.

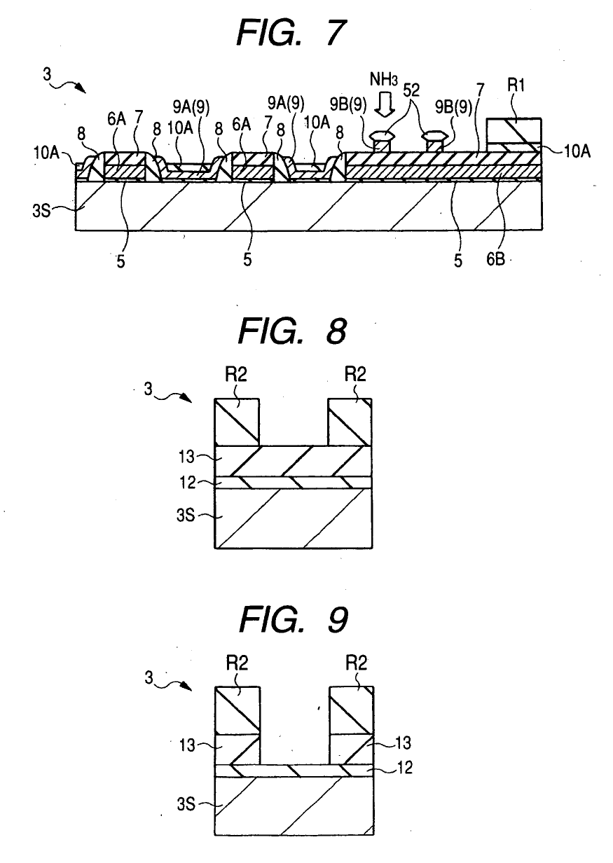

The semiconductor wafer 3 of FIG. 6 is then put in the process chamber Ch of the plasma processing unit 1B illustrated in the lower diagram of FIG. 3, followed by plasma etching of the conductor film 9 over the main surface of the semiconductor wafer 3, for example, with carbon tetrafluoride (CF₄) or a mixed gas of oxygen (O₂) and argon (Ar). FIG. 7 is a fragmentary cross-sectional view of the semiconductor wafer 3 which has finished the plasma etching. In this plasma etching, the conductor film 9 exposed from the antireflective film 10A is removed and a conductor pattern 9A for the formation of a floating gate electrode is formed between two adjacent auxiliary gate electrodes 6A. As described above, however, the salt 52 which has remained on the main surface in the peripheral region of the semiconductor wafer 3 acts as an etching mask and an unintended conductor pattern 9B is also formed over the main surface in the peripheral region of the semiconductor wafer 3. This conductor pattern 9B causes a step difference on the lower layer and becomes a cause for short-circuit failure or disconnection failure of interconnects which will be formed above the conductor pattern 9b in the later steps. This results in the problem such as deterioration in reliability and production yield of the semiconductor integrated circuit device.

FIGS. 8 to 11 are fragmentary cross-sectional views of the semiconductor wafer 3 during the formation steps of an element isolation trench over the main surface of the semiconductor wafer 3.

FIG. 8 is a fragmentary cross-sectional view of the semiconductor wafer 3 before plasma etching. The semiconductor wafer 3 has insulating films 12 and 13 deposited over the main surface (device surface) of the substrate 3S in the order of mention. The insulating film 12 is made of, for example, silicon oxide (SiO₂), while the insulating film 13 is made of, for, example, silicon nitride (Si_{3N}₄). Over the insulating film 13, a resist pattern R2 for the formation of an element isolation trench is formed.

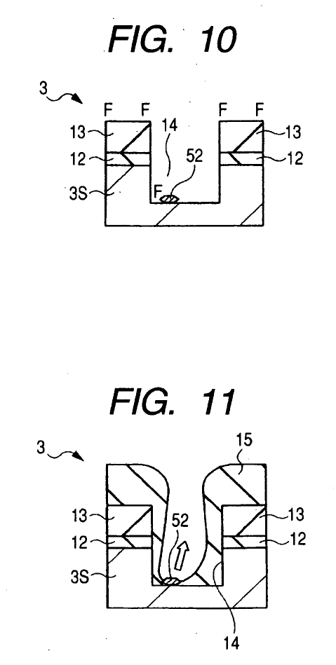

The insulating film 13 exposed from the resist pattern R2 is plasma-etched as illustrated in FIG. 9, followed by removal of the resist pattern R2 by ashing. The semiconductor wafer 3 is then put in the process chamber Ch of the plasma processing unit 1A illustrated in the upper diagram of FIG. 3 and the insulating film 12 and substrate 3S exposed from the insulating film 13 are plasma-etched, for example, with carbon tetrafluoride (CF₄) or a mixed gas of CHF₃ and argon (Ar). By this etching, an element isolation trench 14 is formed in the substrate 3S as illustrated in FIG. 10. In this stage, fluorine (F) is adsorbed to the surface of the semiconductor wafer 3.

The semiconductor wafer 3 is then carried out from the process chamber Ch of the plasma processing unit 1A illustrated in the upper diagram of FIG. 3, carried out from the load lock chamber L/L of the plasma processing unit 1A and put in the process chamber Ch of the plasma processing unit 1B illustrated in the lower diagram of FIG. 3 via the transport system while putting it in the carrier 4. During this operation, the salt 52 is formed on the surface of the semiconductor wafer 3 as illustrated in FIG. 10 because of a similar reason to that described above. FIG. 10 illustrates the salt 52 attached to the bottom of the element isolation trench 14.

The semiconductor wafer 3 is then ashed with a gas containing oxygen (O₂) in the process chamber Ch of the plasma processing unit 1B. The salt 52 remains on the surface of the semiconductor wafer 3 without being removed even after ashing.

The semiconductor wafer 3 is then carried out from the plasma processing unit 1B and then transported to a unit for depositing an insulating film. In this unit, as illustrated in FIG. 11, an insulating film 15 made of, for example, silicon oxide is deposited over the main surface of the semiconductor wafer 3 by CVD (Chemical Vapor Deposition). The salt 52 is melted and gasified in this deposition step of the insulating film 15 because it has a melting point of for example, about 124.6° C. As a result, voids may be formed in the element isolation trench 14.

In this Embodiment, the amount of amines in the EFEM chamber MC of the EFEM unit 2 upstream of the plasma processing unit 1 is adjusted to be smaller than that of amines in the clean room outside the EFEM chamber MC. This makes it possible to suppress the reaction between fluorine used for plasma processing and amines (alkali contaminants) in the EFEM chamber MC and thereby suppress the formation of the salt so that the phenomenon that the salt acts as an etching mask in the steps after plasma processing or the salt becomes a cause for the formation of voids can be reduced or prevented. As a result, the semiconductor integrated circuit device is able to have improved reliability.

A specific example of the structure of a manufacturing apparatus of the semiconductor integrated circuit device of this embodiment will next be described.

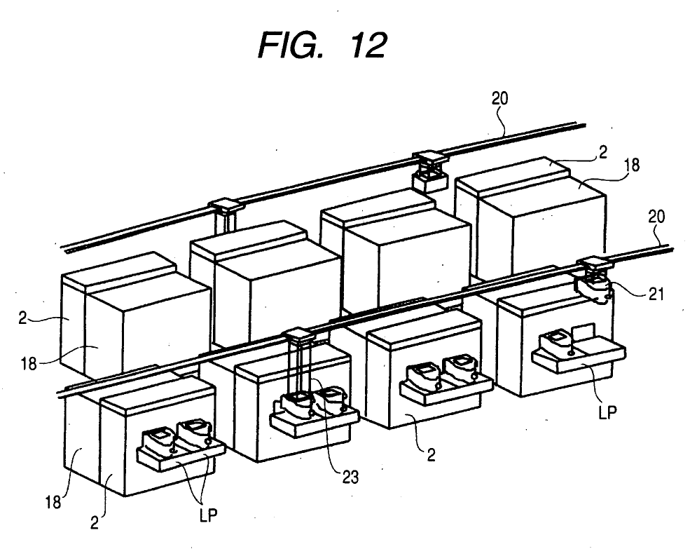

FIG. 12 is a fragmentary perspective view illustrating one example of an intrabay transport portion of a semiconductor manufacture line of this Embodiment.

A plurality of manufacturing apparatuses 18 are arranged in this semiconductor manufacture line. The manufacturing apparatuses 18 each has, in addition to the plasma processing system P, various units used in the manufacturing steps of a semiconductor integrated circuit device, such as heat treatment unit, ion injection unit, film forming unit, washing unit, photoresist application unit, and exposure unit. Each manufacturing apparatus 18 has, upstream thereof, the EFEM unit 2.

In a ceiling-level space of this semiconductor manufacture line, transport rails (transport system TRS) 20 are disposed along the arrangement direction of a plurality of the manufacturing apparatuses 18. This transport rail 20 has a transport means (transport system TRS) such as OHT (Overhead Hoist Transport) disposed movable along the transport rail 20. The OHT is an unmanned transport vehicle running, in the ceiling-level space, along the transport rail 20. The OHT can be moved up and down by a hoist mechanism and this makes it possible to move the carrier 4 between the transport rail 20 and the load port LP of the EFEM unit 2. The transport means 21 is not limited to the OHT and can be replaced by various means. For example, RGV (Rail Guided Vehicle) or AGV (Automatic Guided Vehicle) may be employed.

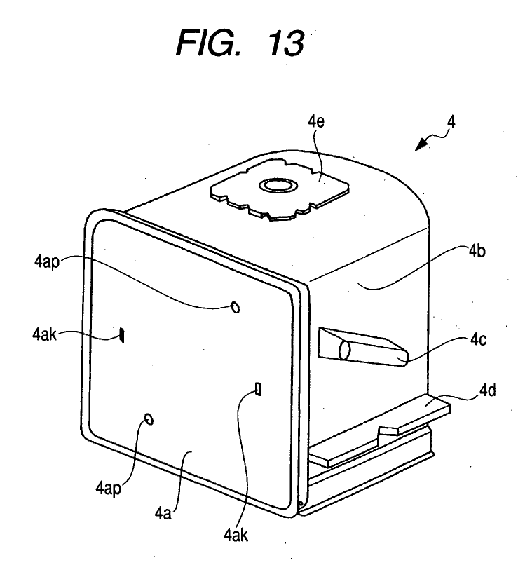

FIG. 13 illustrates the FOUP which is one examples of the carrier 4. This FOUP is a closed type carrier which is defined in SEMI standard E47.1 and used for the transport and storage of a 300-mm wafer used in mini-environment system semiconductor plants.

A shell 4B of this FOUP is a portion defining the outline of a container for storing a plurality of semiconductor wafers 3 therein. On one side surface of this shell 4b, an opening portion is made, through which the semiconductor wafers 3 are transferred. At this opening portion, the carrier door 4a is openably and closably attached. On the outside wall of this carrier door 4a, a registration pin hole 4ab for positioning the carrier 4, and a latch key hole 4ak for opening the carrier door 4a are formed.

The shell 4b has, on another side surface thereof, a manual hand 4c and a side rail 4d. The manual hand 4c is used, for example, when the carrier 4 is lift up manually. The side rail 4c is used, for example, when the carrier 4 is scooped up by a robot. The shell 4b has, on the upper surface thereof, a top flange 4e for grasping the carrier 4 when the carrier 4 is automatically transported by the robot. The shell 4b has, on the bottom thereof, a breathing filter.

The carrier 4 is however not limited to the FOUP and an open type carrier such as open cassette may be used instead. As the closed type carrier, SMIF (Standard Mechanical Interface) or FOSB (Front Opening Shipping Box) may also be employed.

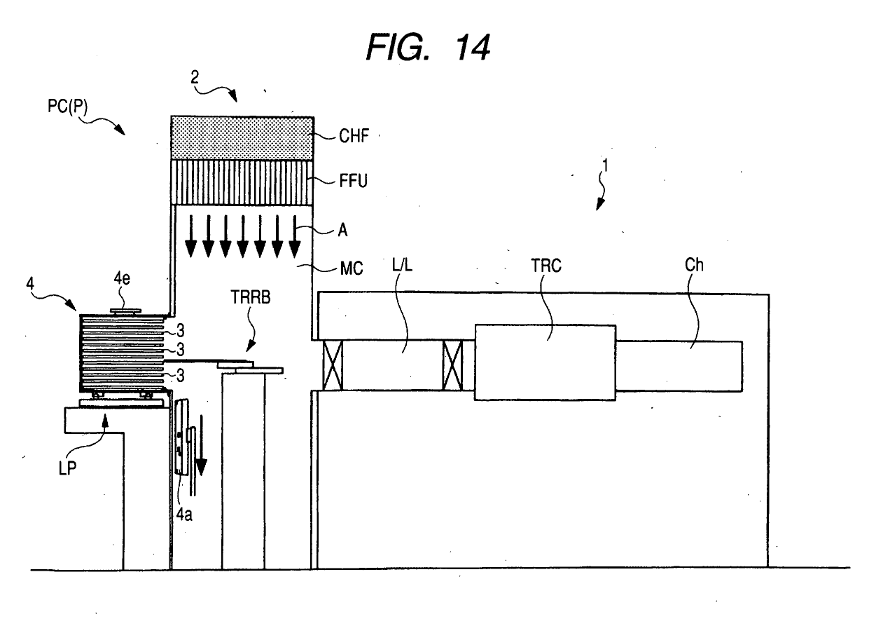

FIG. 14 illustrates the structure of a plasma processing system PC of this embodiment which is a part of the above-described manufacturing apparatus 18. In the plasma processing system PC of this embodiment, a chemical filter CHF is integrated with a fan filter unit FFU of an EFEM unit 2. The chemical filter CHF is an alkali removal filter through which a chemical contaminant gas (foreign matter) such as an alkali (amine such as ammonia (NH₃)) gas is decomposed and thereby removed. As a filter material of the chemical filter CHF, an ion exchange resin is, for example, employed.

Such a chemical filter CHF enables reduction of the amount of an alkali gas in the EFEM chamber MC to 80 to 95% or less of the alkali gas in a clean room outside the plasma processing system PC, whereby the concentration of amines such as ammonia (NH₃) in the EFEM chamber MC or carrier 4 of the plasma processing system PC can be reduced to 1 μg/m³ or less, moreover 0.5 μg/m³ or less, which is smaller than that (for example, from about 5 to 20 μg/m³) of the amines in the clean room outside the EFEM chamber MC. The other structure of the plasma processing system is similar to that described in FIGS. 1 and 2. The cleanliness of the clean room outside the plasma processing system PC and the cleanliness of the EFEM chamber MC are also similar to those described in FIGS. 1 and 2.

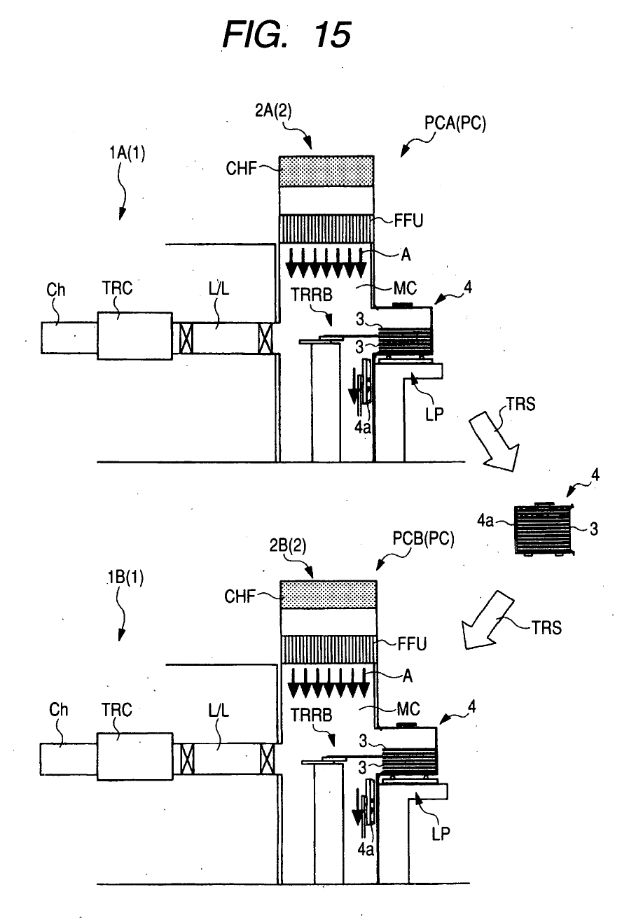

FIG. 15 illustrates an example of plasma processing using two plasma processing systems PCA and PCB (PC) having the structure as shown in FIGS. 14 and 2.

A semiconductor wafer 3 is subjected to plasma processing such as plasma etching, for example, with a gas containing fluorine (F) in a process chamber Ch of a plasma processing unit 1A (1) of the plasma processing system PCA illustrated in the upper diagram of FIG. 15. This etching step corresponds to etching of the antireflective film or etching for forming a trench in the substrate 3S. Fluorine is adsorbed onto the surface of the semiconductor wafer 3 as described above.

The semiconductor wafer 3 which has finished plasma processing is put in a carrier 4 placed on a load port LP of an EFEM unit 2A via a transport chamber TRC, load lock chamber L/L and EFEM chamber MC. At this time, the concentration of amines in the EFEM chamber MC and carrier 4 is adjusted to be lower than that of amines in the outside clean room by a chemical filter CHF. This makes it possible to suppress the reaction, in the EFEM chamber MC of the plasma processing system PCA and the carrier 4, between the fluorine adsorbed to the surface of the semiconductor wafer 3 as a result of plasma etching and the amines in the EFEM chamber MC or carrier 4, whereby formation of the salt can be suppressed.

Then, the carrier 4 is transported via a transport system TRS. During this transport, the carrier 4 may be stored in the stocker (stock room, stock rack).

Via the transport system TRS, the carrier 4 is placed on a load port LP of an EFEM unit 2B (2) of the plasma processing system PCB illustrated in the lower diagram of FIG. 15. The semiconductor wafer 3 in the carrier 4 is then put in a process chamber Ch of a plasma processing unit 1B (1) via an EFEM chamber MC of the EFEM unit 2B. Also during this operation, the concentration of amines in the EFEM chamber MC is adjusted to be lower than that of the amines in the outside clean room by a chemical filter CHF. This makes it possible to suppress the reaction, in the EFEM chamber MC of the plasma processing system PCB, between the fluorine adsorbed to the surface of the semiconductor wafer 3 as a result of plasma etching and the amines in the EFEM chamber MC or carrier 4, whereby formation of the salt can be suppressed further.

The semiconductor wafer 3 is then subjected to plasma processing in the process chamber Ch of the plasma processing unit 1B. This plasma step corresponds to the above-described etching of the polycrystalline silicon film or ashing after formation of the trench in the substrate 3S.

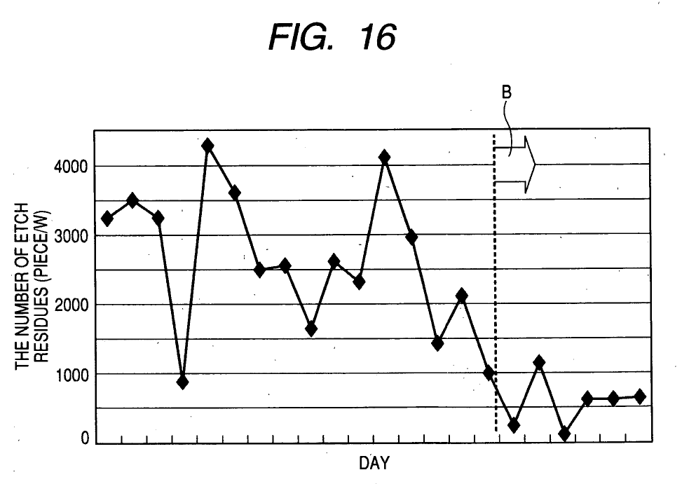

Thus, by installing the chemical filter CHF in this Embodiment, the concentration of amines in the EFEM chamber MC or carrier 4 can be made lower than that of the amines in the clean room outside the EFEM chamber MC. This makes it possible to suppress the reaction between fluorine adsorbed onto the surface of the semiconductor wafer 3 which has finished plasma processing such as plasma etching and amines in the EFEM chamber MC or carrier 4, whereby the formation of the salt is suppressed. Therefore, the phenomenon that the salt serves as an etching mask in the steps after the plasma processing or the salt becomes a cause for the formation of voids can be suppressed or prevented. This results in the improvement in the reliability and production yield of the semiconductor integrated circuit device. FIG. 16 is a graph showing one example of the effect brought by the installment of the chemical filter CHF. The number of etch residues after the days indicated by an arrow B shows the effect of the chemical filter CHF. This graph shows that the number of etch residues decreases by the installment of the chemical filter CHF.

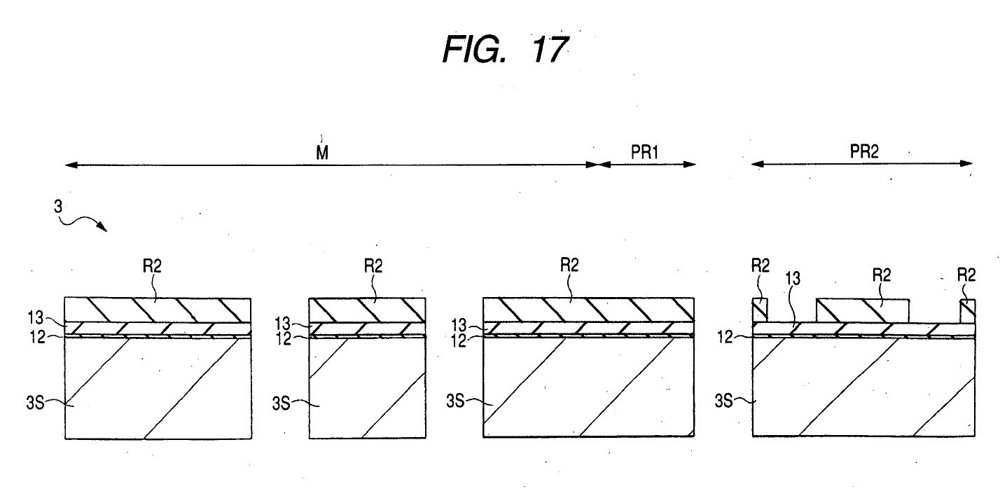

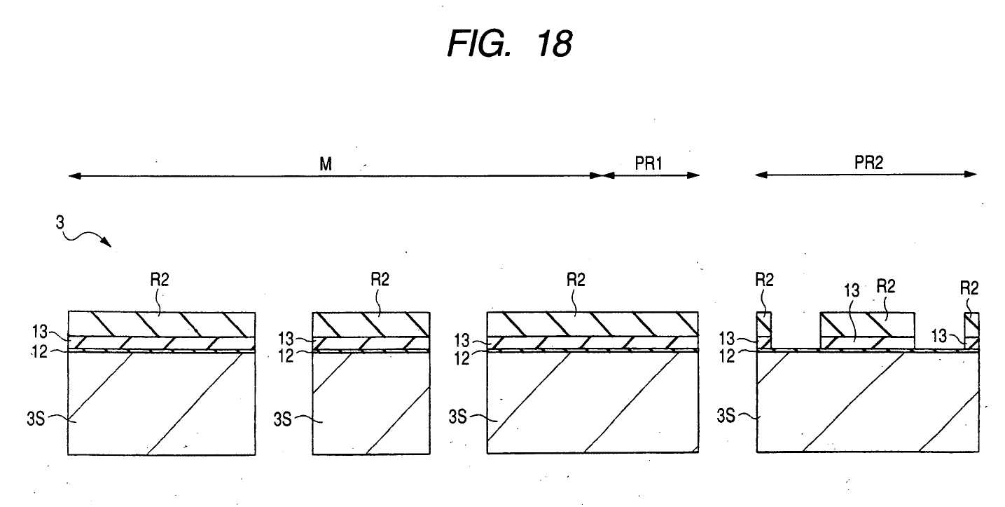

An example of the manufacturing process of a semiconductor integrated device according to this Embodiment will next be described based on FIGS. 17 to 26. FIGS. 17 to 26 are fragmentary cross-sectional views of the semiconductor wafer 3 during the manufacturing steps of a semiconductor integrated circuit device having an AG-AND flash memory of 1GB. In FIGS. 17 to 26, M represents a memory region, PR1 represents a first peripheral region adjacent to the memory region, and PR2 represents a second peripheral region distant from the memory region. In FIGS. 17 to 26, the leftmost one is a cross-sectional view of the semiconductor wafer 3 cut along a direction parallel to a word line; the second left one is a cross-sectional view of the semiconductor wafer 3 cut along a direction perpendicular to the word line; the third left one is a cross-sectional view of the semiconductor wafer 3 cut along a direction perpendicular to the word line; and the rightmost one is a cross-sectional view of the semiconductor wafer 3 cut along a direction perpendicular to a gate electrode.

As illustrated in FIG. 17, after formation of the insulating film 12 over the main surface (device surface) of a substrate 3S of a semiconductor wafer 3, which substrate is made of p type silicon (Si) single crystal, by thermal oxidation, the insulating film 13 is laid over the insulating film 12 by CVD. After a series of lithography steps such as resist application, exposure and development, a resist pattern R2 for the formation of an isolation trench is formed over the insulating film 13. The resist pattern R2 has a planar shape to expose therefrom the formation region of the isolation trench and cover the other region with the pattern.

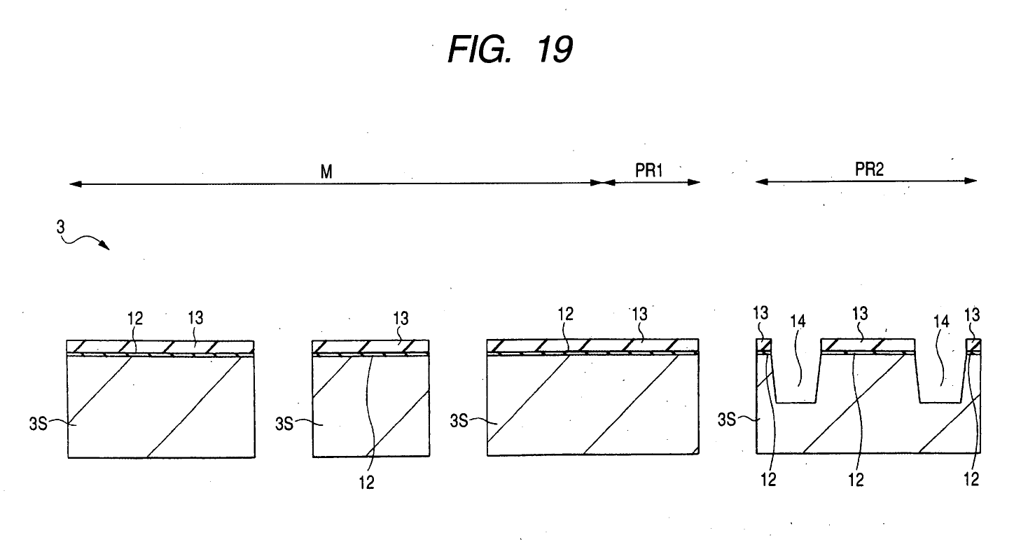

With this resist pattern R2 as an etching mask, the insulating film 13 exposed from the resist pattern R2 is etched as illustrated in FIG. 18, followed by removal of the resist pattern R2 by ashing. The resulting semiconductor wafer 3 is put in the process chamber (first etching chamber) Ch of the plasma processing unit (first etching unit) 1A(1) at the plasma processing system PCA in FIG. 15 and the insulating film 12 and substrate 3S exposed from the insulating film 13 are plasma-etched, for example, with carbon tetrachloride (CF₄) or a mixed gas of CHF₃ and argon (Ar). By this etching, an element isolation trench 14 is formed in the substrate 3S as illustrated in FIG. 19. In this stage, fluorine (F) is adsorbed to the surface of the semiconductor wafer 3. Then, the semiconductor wafer 3 which has finished plasma etching was put in the carrier 4 placed in the load port (first load port) LP of EFEM unit (first module unit) 2A via transport chamber TRC, load lock chamber L/L and EFEM chamber (first chamber) MC of the plasma processing system PCA. During this operation, the concentrations of amines in the EFEM chamber MC of the plasma processing system PCA and in the carrier 4 are adjusted to be lower than the concentration of amines in a clean room outside of the chamber by the chemical filter CHF of the EFEM unit 2A of the plasma processing system PCA. This makes it possible to suppress the reaction, in the EFEM chamber MC of the plasma processing system PCA and carrier 4, between fluorine adsorbed to the surface of the semiconductor wafer 3 as a result of the plasma etching and amines in the EFEM chamber MC or carrier 4, leading to suppression of the formation of the above-described salt.

The carrier 4 is then transported from the load port LP of the plasma processing system. PCA via the transport system TRS. During this transport, the carrier 4 may be put in a stocker (storage house, storage rack). Via the transport system TRS, the carrier 4 is placed on the load port (third load port) LP of the EFEM unit (third module unit) of the plasma processing system PCB illustrated in the lower diagram of FIG. 15. The semiconductor wafer 3 in the carrier 4 is put in the process chamber (plasma process chamber) of the plasma processing unit (first post-processing unit) 1B(1) via the EFEM chamber (third chamber) MC of the EFEM unit 2B. Also during this operation, the concentration of amines in the EFEM chamber MC of the plasma processing system PCB is adjusted to be lower than that of amines in a clean room outside the chamber by the chemical filter CHF of the EFEM unit 2B of the plasma processing system PCB. This makes it possible to suppress the reaction, in the EFEM chamber MC of the plasma processing system PCB, between fluorine adsorbed to the surface of the semiconductor wafer 3 as a result of the plasma etching and amines in the EFEM chamber MC or carrier 4, leading to suppression of the formation of the above-described salt. In the process chamber Ch of the plasma processing unit 1B, the semiconductor wafer 3 is then subjected to plasma ashing with a gas containing, for example, oxygen (O₂), whereby the resist material is mainly removed as a foreign matter.

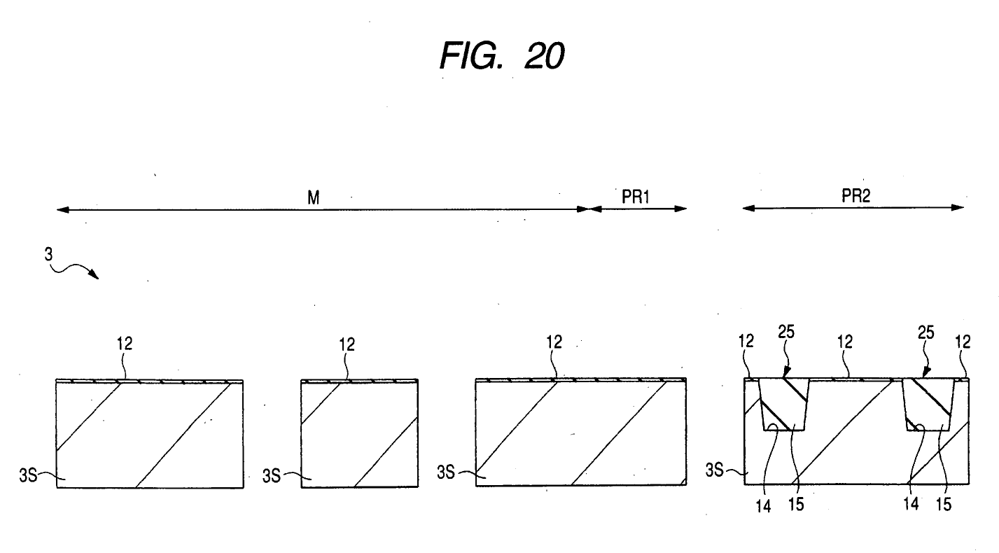

The semiconductor wafer 3 is then transported to a film forming apparatus. In the film forming apparatus, an insulating film made of, for example, silicon oxide is deposited over the main surface of the semiconductor wafer 3 by CVD, followed by etching of an unnecessary portion outside of the element isolation trench 14 from the insulating film by CMP (Chemical Mechanical Polishing) or etchback method. By this etching, an element isolation portion 25 is formed as illustrated in FIG. 20. The element isolation portion 25 is formed by filling an insulating film 15 in the element isolation trench 14. In this Embodiment, the formation of a salt can be suppressed as described above so that generation of voids in the element isolation portion 25 which will otherwise occur by the melting of the salt and gasification of the melted salt can be suppressed or prevented. This results in the improvement of the reliability and production yield of the semiconductor integrated circuit device.

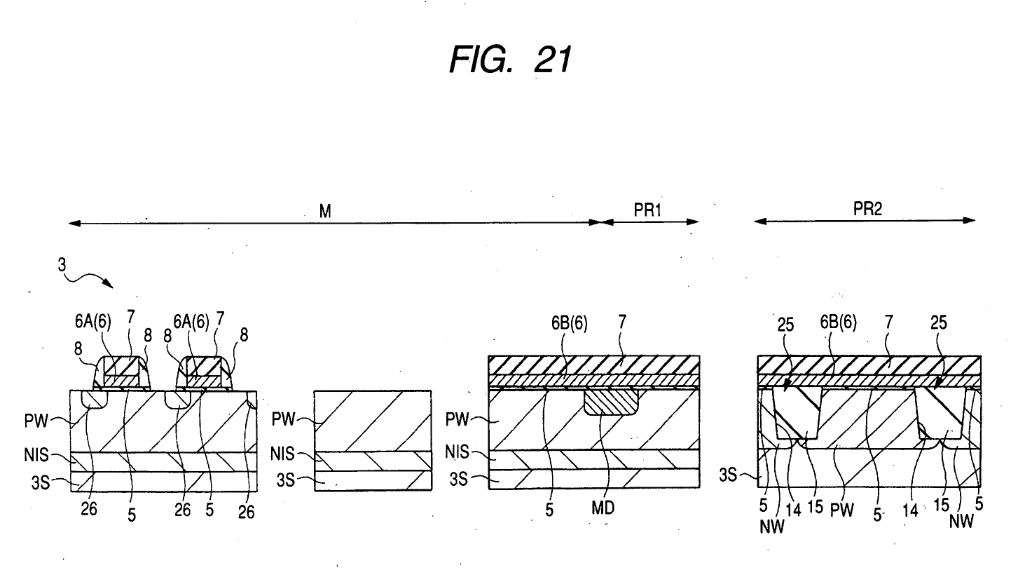

As illustrated in FIG. 21, after formation of an n type implant region NIS, n type well NW and p type well PW by ion implantation or the like method, an impurity for adjusting a threshold value is implanted into a memory region M to form an n type semiconductor region MD. A gate insulating film 5 made of, for example, silicon oxide is formed over the main surface of the substrate 3S by thermal oxidation or the like method, followed by the deposition of a conductor film 6 made of low-resistance polycrystalline silicon over the gate insulating film 5. Then, a cap insulating film 7 made of, for example, silicon oxide is deposited by CVD or the like over the conductor film 6. The conductor film 6 is then patterned by lithography and etching, whereby an auxiliary gate electrode 6A and conductor pattern 6B are formed over the main surface of the substrate 3S.

After deposition of an insulating film made of, for example, silicon oxide over the main surface of the semiconductor substrate 3 by CVD or the like, the insulating film is etched back to form sidewalls 8 over the side surfaces of the auxiliary gate electrode 6A and conductor pattern 6B. Then, an impurity is ion-implanted diagonally to the main surface of the semiconductor wafer 4 to form an n type semiconductor region 26 in a portion of the substrate 3S below one end of the auxiliary gate electrode 6A.

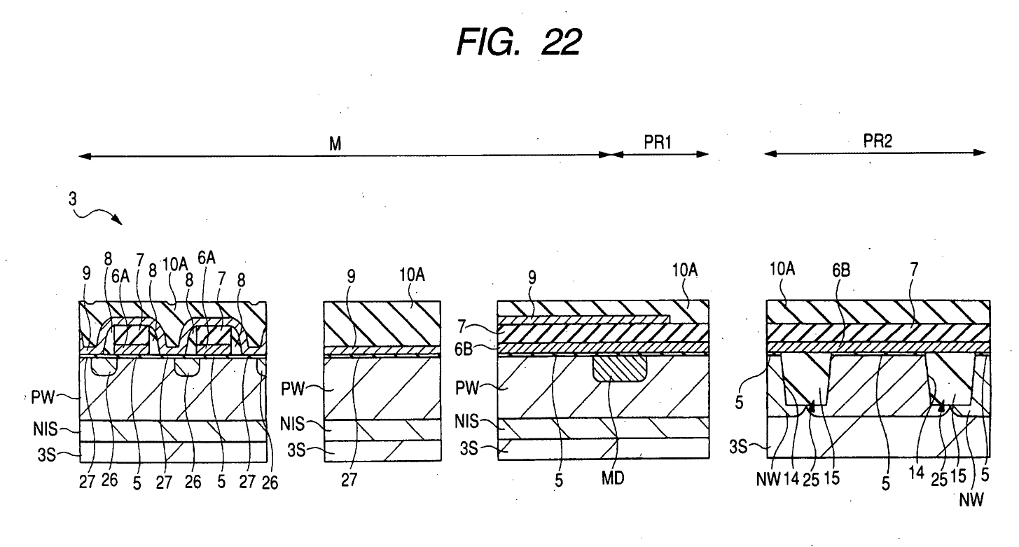

After formation of an insulating film 27 made of, for example, silicon oxide over the main surface of the substrate 3S of the semiconductor wafer 3 by the thermal oxidation method or the like as illustrated in FIG. 22, a conductor film 9 made of, for example, low resistance polycrystalline silicon is deposited over the main surface of the semiconductor wafer 3 by CVD or the like, followed by the deposition of an antireflective film (BARC) 10A by CVD or the like. The antireflective film 10A is made of, for example, a material represented by the following formula (1).
[Chemical Formula 1]

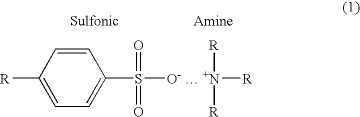

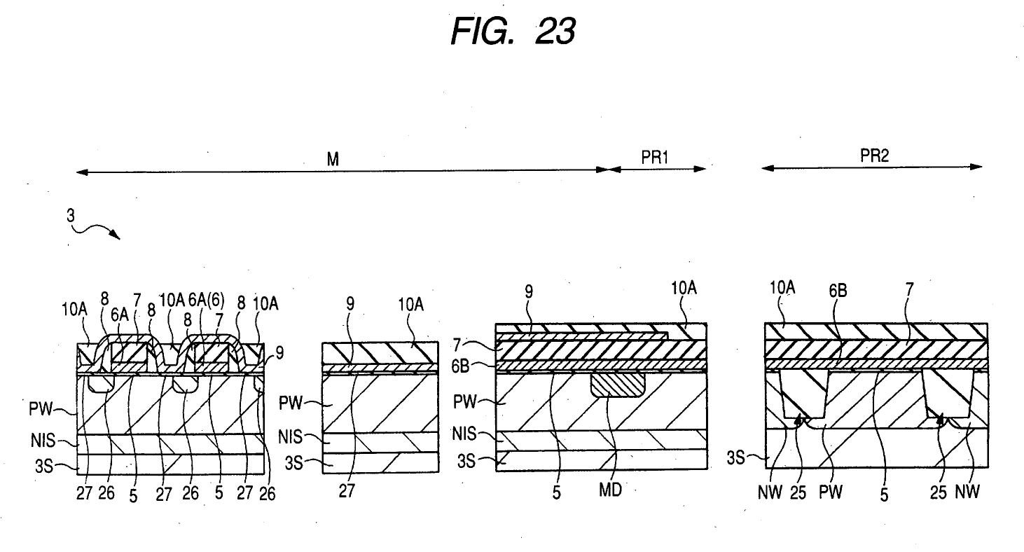

The semiconductor wafer 3 is then put in the process chamber (first etching chamber) Ch of the plasma processing unit (first etching unit) 1A(1) of the plasma processing system PCA illustrated in FIG. 15. The semiconductor wafer 3 is then plasma-etched, for example, with a mixed gas of carbon tetrafluoride (CF₄), oxygen (O₂) and argon (Ar), whereby the antireflective film 10A is etched. FIG. 23 is a fragmentary cross-sectional view of the semiconductor wafer 3 after the plasma etching. A portion of the conductor film 9 over the auxiliary gate electrode 6A is exposed, while the other portion of the conductor film 9 between two adjacent auxiliary gate electrodes 6A is covered with the antireflective film 10A which has remained therebetween. In this stage, fluorine (F) is adsorbed to the surface of the semiconductor wafer 3.

The semiconductor wafer 3 which has finished plasma etching is put in the carrier 4 placed on the load port (first load port) LP of the EFEM unit (first module unit) 2A via the transport chamber TRC, load lock chamber L/L and EFEM chamber (first chamber) MC of the plasma processing system PCA. During this operation, the concentration of amines in the EFEM chamber MC of the plasma processing system PCA and the carrier 4 is adjusted to be lower than that of amines in a clean room outside of the chamber by the chemical filter CHF of the EFEM unit 2A of the plasma processing system PCA. This makes it possible to suppress the reaction, in the EFEM chamber MC of the plasma processing system PCA and carrier 4, between fluorine adsorbed to the surface of the semiconductor wafer 3 as a result of the plasma etching processing and amines in the EFEM chamber MC and carrier 4, leading to suppression of the formation of the above-described salt.

The carrier 4 is then transported from the load port LP of the plasma processing system PCA via the transport system TRS. During this transport, the carrier 4 may be put in a stocker (storage house, storage rack). Via the transport system TRS, the carrier 4 is placed on the load port (second load port) LP of the EFEM unit (second module unit) 2B (2) of the plasma processing unit (second etching unit) 1B (1) of the plasma processing system PCB illustrated in the lower diagram of FIG. 15. The semiconductor wafer 3 in the carrier 4 is put in the process chamber (second etching chamber) of the plasma processing unit 1B (1) via the EFEM chamber (second chamber) MC of the EFEM unit 2B. Also during this operation, the concentration of amines in the EFEM chamber MC of the plasma processing system PCB is adjusted to be lower than that of amines in a clean room outside the chamber by the chemical filter CHF of the EFEM unit 2B of the plasma processing system PCB. This makes it possible to suppress the reaction, in the EFEM chamber MC of the plasma processing system PCB, between fluorine adsorbed to the surface of the semiconductor wafer 3 as a result of the plasma etching and amines in the EFEM chamber MC or carrier 4 further, leading to suppression of the formation of the above-described salt further.

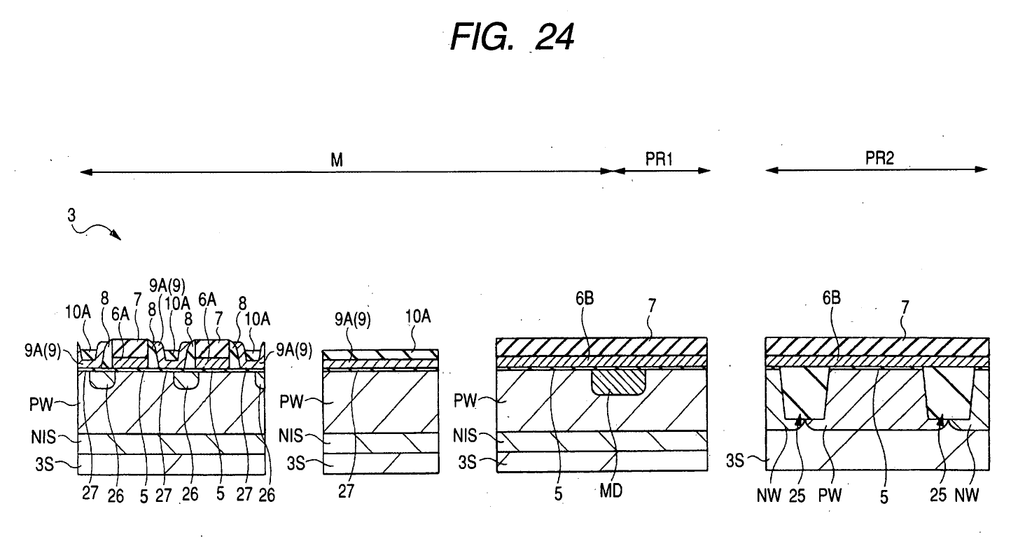

The semiconductor wafer 3 is then plasma-etched, for example, with carbon tetrafluoride (CF₄) or a mixed gas of CHF₃ and argon (Ar) in the process chamber Ch of the plasma processing unit 1B, whereby the conductor film 9 exposed from the antireflective 10A is etched. FIG. 24 is a fragmentary cross-sectional view of the semiconductor wafer 3 after the plasma etching. By this plasma etching, a conductor pattern 9A for the formation of a floating gate electrode is formed between two adjacent auxiliary gate electrodes 6A. When the salt exists on the surface of the semiconductor wafer 3, it acts as an etching mask and an unintended conductor pattern sometimes remains. This unintended conductor pattern forms a step difference, which will be a cause of short circuit failure or disconnection a failure of interconnects formed above the, conductor pattern in the later steps. As a result, this leads to deterioration in the reliability and production yield of the,semiconductor integrated circuit device. In this Embodiment, on the contrary, the generation of salts can be suppressed so that occurrence of such a problem can be reduced or prevented, leading to improvement in the reliability and production yield of the semiconductor integrated circuit device.

The carrier 4 is transported from the load port LP of the plasma processing system PCB via the transport system TRS. During this transport, the carrier 4 may be put in a stocker, (storage house, storage rack). Via the transport system TRS, the carrier 4 is placed on the load port (third load port) LP of the EFEM unit (third module unit) 2 of the plasma processing unit (first post-processing unit) 1 of another plasma,processing system PC. The semiconductor wafer 3 in the carrier 4 is put in the process chamber (plasma process chamber) Ch of the plasma processing unit 1 via the EFEM chamber MC of the EFEM unit 2. Also during this operation, the concentration of amines in the EFEM chamber (third chamber) MC of the plasma processing system P is adjusted to be lower than that of amines in a clean room outside of the chamber by the chemical filter CHF of the EFEM unit 2 of the plasma processing system P. This makes it possible to suppress the reaction, in the EFEM chamber MC of the plasma processing system P, between fluorine adsorbed to the surface of the semiconductor wafer 3 as a result of the plasma etching and amines in the EFEM chamber MC or carrier 4 further, leading to suppression of the formation of the above-described salt further.

In the process chamber Ch of the plasma processing unit 1 of the plasma processing system P, the semiconductor wafer 3 is subjected to plasma ashing with a gas containing, for example, oxygen (O₂), whereby the resist material is mainly removed as a foreign matter.

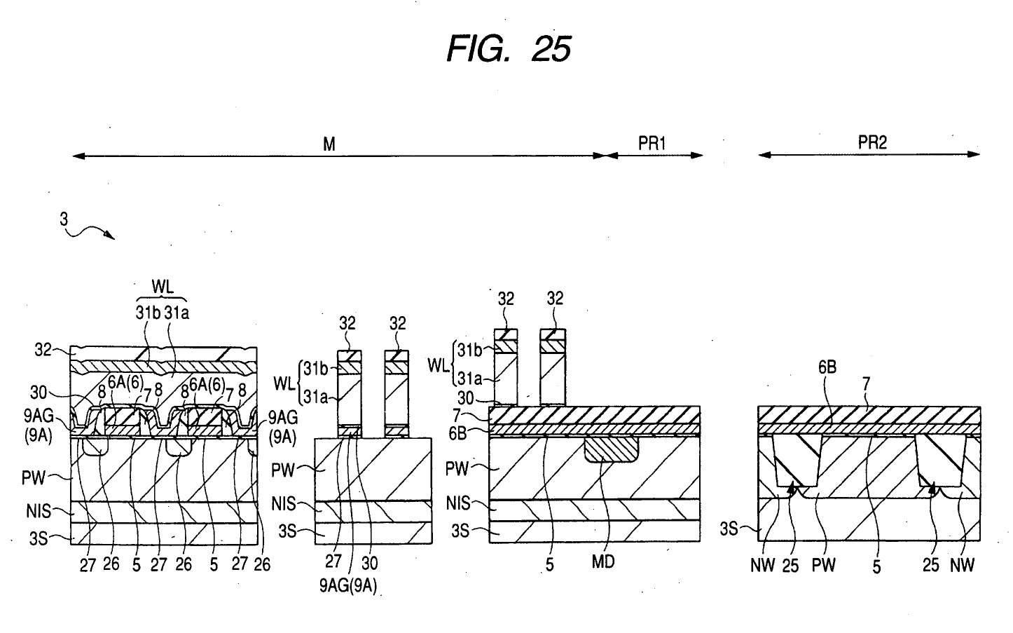

As illustrated in FIG. 25, silicon oxide, silicon nitride and silicon oxide are, for example, formed successively in the order of mention over the main surface of the semiconductor wafer 3 to form an interlayer insulating film 30. During this operation, existence of the above-described salt under the thin interlayer insulating film 30 sometimes deteriorate the quality of the interlayer insulating film 30. In this Embodiment, on the other hand, generation of the salt can be suppressed, so that the reliability of the interlayer insulating film 30 can be improved. Over the interlayer insulating film 30, a conductor film 31a, made of, for example, low resistance polycrystalline silicon, a conductor film 31b made of, for example, tungsten silicide and a cap insulating film 32 made of silicon oxide are deposited successively in the order of mention, followed by patterning of them by lithography and etching, whereby word line WL and floating gate electrode 9AG (9A) are formed.

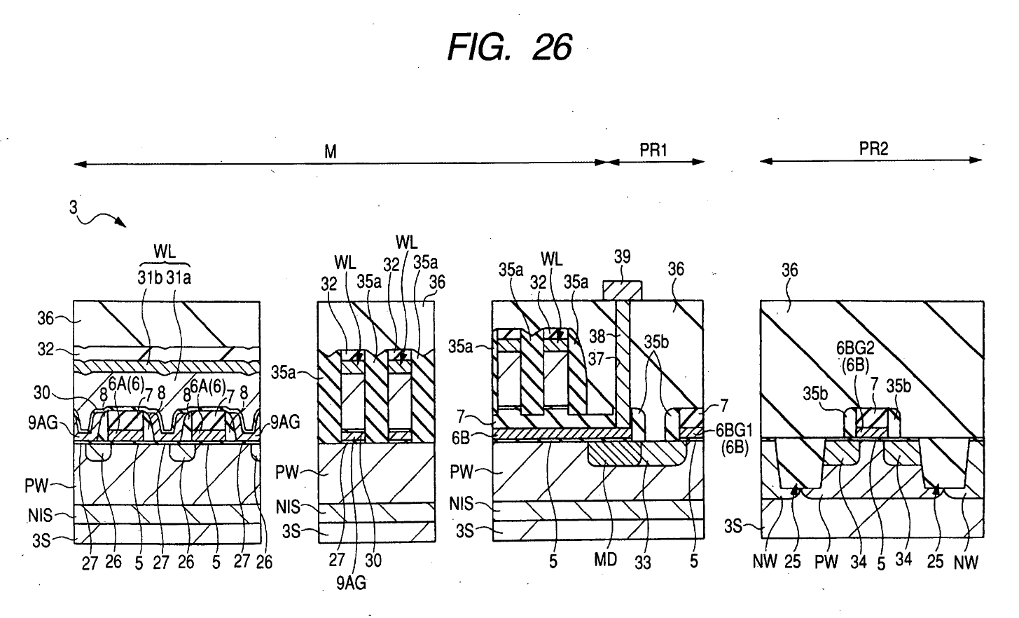

As illustrated in FIG. 26, the conductor pattern 6B is patterned by lithography and etching to form gate electrodes 6BG1 and 6BG2 (6B) in the peripheral regions PR1 and PR2, followed by the formation of n type semiconductor regions 33 and 34 for source drain. An insulating film made of, for example silicon oxide is deposited by CVD or the like over the main surface of the semiconductor wafer 3. It is then etched back to form an insulating film 35a over the side surface of the word line WL and between two adjacent word lines WL, and at the same time, to form sidewalls 35b on the side surfaces of the gate electrodes 6BG1 and 6BG2. After deposition of an insulating film 36 made of, for example, silicon oxide over the main surface of the semiconductor wafer 3 by CVD or the like method, a contact hole 37 is formed in the insulating film 36. A conductor film is filled in the contact hole 37 to form a plug 38 and then, a first-level interconnect 39 made of a conductor film such as aluminum or tungsten is formed over the insulating film 36. In this Embodiment, formation of a salt can be reduced as described above so that occurrence of short-circuit failure or disconnection failure in the first-level interconnect 39 or the like can be reduced or prevented, resulting in the improvement in the reliability and production yield of the semiconductor integrated circuit device.

The invention completed by the present inventors was described specifically based on some embodiments. The present invention is not limited to or by these embodiments, but needless to say, it may include various variations and modifications without departing from the scope of the present invention

The invention may be applied to, for example, SAC (Self Aligned Contact hole) processing technology. In SAC processing technology, an interlayer insulating film made of, for example, silicon oxide is formed, via an etching stopper insulating film made of, for example, silicon nitride, over the substrate of a semiconductor wafer or over interconnects (including gate electrodes) formed over the substrate. When contact holes or the like are formed in this interlayer insulating film, plasma etching is performed while setting an etching selectivity between silicon oxide and silicon nitride high. As an etching gas, a primary reaction gas such as C₄F₈ is used. Also in this case, by installing an alkali removing chemical filter in the EFEM unit upstream of the plasma etching unit, the amount of amines in the EFEM chamber can be made smaller than that in the clean room, whereby the formation of a salt can be suppressed. This results in the improvement in the reliability and production yield of the semiconductor integrated circuit device to which the SAC processing technology is applied.

The present invention made by the present inventors was, as described above, applied to the manufacturing method of a semiconductor integrated circuit device which is included in an industrial field becoming the background of the invention. Not only to this field, but it can be applied to various fields, for example, a manufacturing method of a micromachine.

The present invention can be used in the manufacturing industry of semiconductor integrated circuit devices.

What is claimed is:

1. A manufacturing method of a semiconductor integrated circuit device, comprising the steps of:
(a) preparing a wafer;
(b) placing a carrier having the wafer put therein on a first load port of a first module unit upstream of a first etching unit;
(c) putting the wafer, which is in the carrier on the first load port, in a first etching chamber of the first etching unit via a first chamber of the first module unit;
(d) subjecting the wafer to first plasma etching in the first etching chamber by using a first gas containing fluorine;
(e) putting the wafer, which has finished the first plasma etching, in the carrier on the first load port via the first chamber;
(f) transporting the carrier having the wafer, which has finished the first plasma etching, put therein to a second load port of a second module unit upstream of a second etching unit through a transport route and placing the carrier on the second load port;
(g) putting the wafer, which is in the carrier on the second load port, in a second etching chamber of the second etching unit via a second chamber of the second module unit;
(h) subjecting the wafer to second plasma etching in the second etching chamber by using a second gas containing fluorine; and
(i) putting the wafer, which has finished the second plasma etching, in the carrier on the second load port via the second chamber,
wherein the first module unit is equipped with a chemical filter for alkali removal to adjust, in the step (e), the amount of an alkali contaminant in the first chamber to be smaller than the amount of an alkali contaminant outside the first chamber.

2. A manufacturing method of a semiconductor integrated circuit device according to claim 1, wherein the second module unit is equipped, with a chemical filter for alkali removal to adjust, in the step (g), the amount of an alkali contaminant in the second chamber to be smaller than the amount of an alkali contaminant outside the second chamber.

3. A manufacturing method of a semiconductor integrated circuit device according to claim 2, further comprising, after the step (i), the steps of:
(j) transporting the carrier having the wafer, which has finished the second plasma etching, put therein to a third load port of a third module unit upstream of a first post-processing unit via the transfer route and placing the carrier on the third load port;
(k) putting the wafer, which is in the carrier on the third load port, in a plasma processing chamber of the first post-processing unit via a third chamber of the third module unit;
(l) subjecting the wafer to plasma processing with a third gas containing fluorine in the plasma processing chamber; and
(m) putting the wafer, which has finished the plasma processing, in the carrier on the third load port via the third chamber,
wherein the third module unit is equipped with a chemical filer for alkali removal to adjust, in the steps (i) and (k), the amount of an alkali contaminant in the second and third chambers to be smaller than the amount of an alkali contaminant outside the second and third chambers.

4. A manufacturing method of a semiconductor integrated circuit device according to claim 3, wherein the first post-processing unit is an ashing unit and the plasma processing in the step (1) is ashing.

5. A manufacturing method of a semiconductor integrated circuit device according to claim 1,
wherein the first plasma etching is etching for the removal of an antireflective film over the wafer, and
wherein the second plasma etching is etching for the removal of a polycrystalline silicon film exposed from the antireflective film over the wafer.

6. A manufacturing method of a semiconductor integrated circuit device according to claim 1, wherein the first gas and the second gas each has a fluorocarbon gas.

7. A manufacturing method of a semiconductor integrated circuit device according to claim 1, wherein the carrier is a closed type carrier.

8. A manufacturing method of a semiconductor integrated circuit device according to claim 7, wherein the carrier is any one of FOUP, FOSB, FIMS, SMIF and unified pod.

9. A manufacturing method of a semiconductor integrated circuit device, comprising the steps of:
(a) preparing a wafer;
(b) placing a carrier having the wafer put therein on a first load port of a first module unit upstream of a first etching unit;
(c) putting the wafer, which is in the carrier on the first load port, in a first etching chamber of the first etching unit via a first chamber of the first module unit;
(d) subjecting the wafer to first plasma etching in the first etching chamber by using a first gas containing fluorine; and
(e) putting the wafer, which has finished the first plasma etching, in the carrier on the first load port via the first chamber,
wherein the first module unit is equipped with a chemical filer for alkali removal to adjust, in the step (e), the amount of an alkali contaminant in the first chamber to be smaller than the amount of an alkali contaminant outside the first chamber.

10. A manufacturing method of a semiconductor integrated circuit device according to claim 9, further comprising, after the step (e), the steps of:
(f) transport the carrier having the wafer, which has finished the first plasma etching, put therein to a third load port of a third module unit upstream of a first post-processing unit through a transfer route and placing the carrier on the third load port;
(g) putting the wafer, which is in the carrier on the third load port, in a plasma processing chamber of the first post-processing unit via a third chamber of the third module unit;
(h) subjecting the wafer to plasma processing in the plasma processing chamber by using a third gas; and
(i) putting the wafer, which has finished the plasma processing, in the carrier on the third load port via the third chamber,
wherein the third module unit is equipped with a chemical filer for alkali removal to adjust, in the steps (e) and (g), the amount of an alkali contaminant in the first and third chambers to be smaller than the amount of an alkali contaminant outside the first and third chambers.

11. A manufacturing method of a semiconductor integrated circuit device according to claim 10, wherein the first post-processing unit is an ashing unit and the plasma processing in the step (h) is ashing.

12. A manufacturing method of a semiconductor integrated circuit device according to claim 9, wherein the first plasma etching is conducted to form a trench in the wafer.

13. A manufacturing method of a semiconductor integrated circuit device according to claim 9, wherein the first and third gases each has a fluorocarbon gas.

14. A manufacturing method of a semiconductor integrated circuit device according to claim 9, wherein the carrier is a closed type carrier.

15. A manufacturing method of a semiconductor integrated circuit device according to claim 14, wherein the carrier is any one of FOUP, FOSB and SMIF.

16. A manufacturing method of a semiconductor integrated circuit device, comprising the steps of:
(a) preparing a wafer;
(b) placing a carrier having the wafer put therein on a first load port of a first module unit upstream of a first etching unit;
(c) putting the wafer, which is in the carrier on the first load port, in a first etching chamber of the first etching unit via a first chamber of the first module unit;
(d) subjecting the wafer to first plasma etching in the first etching chamber by using a first gas containing fluorine and thereby forming, in the main surface of the wafer, a trench extending in a direction crossing with the main surface; and
(e) putting the wafer, which has finished the first plasma etching, in the carrier on the first load port via the first chamber,
wherein the first module unit is equipped with a chemical filer for alkali removal to adjust, in the step (e), the amount of an alkali contaminant in the first chamber to be smaller than the amount of an alkali contaminant outside the first chamber.

17. A manufacturing method of a semiconductor integrated circuit device according to claim 16, further comprising, after the step (e), the steps of:
(f) transporting the carrier having the wafer, which has finished the first plasma etching, put therein to a third load port of a third module unit upstream of a first post-processing unit through a transfer route and placing the carrier on the third load port;
(g) putting the wafer, which is in the carrier on the third load port, in a plasma processing chamber of the first post-processing unit via a third chamber of the third module unit;
(h) subjecting the wafer to plasma processing in the plasma processing chamber by using a third gas; and
(i) putting the wafer, which has finished the plasma processing, in the carrier on the third load port via the third chamber,
wherein the third module unit is equipped with a chemical filer for alkali removal to adjust, in the steps (e) and (g), the amount of an alkali contaminant in the first and third chambers to be smaller than the amount of an alkali contaminant outside the first and third chambers.

18. A manufacturing method of a semiconductor integrated circuit device according to claim 17, wherein after the step (i), an insulating film is filled in the trench formed in the main surface of the wafer.

19. A manufacturing method of a semiconductor integrated circuit device according to claim 16, wherein the first post-processing unit is an ashing unit and plasma processing in the step (h) is ashing.

20. A manufacturing method of a semiconductor integrated circuit device according to claim 16, wherein the first and third gases each has a fluorocarbon gas.

21. A manufacturing method of a semiconductor integrated circuit device according to claim 16, wherein the carrier is a closed type carrier.

22. A manufacturing method of a semiconductor integrated circuit device according to claim 21, wherein the carrier is any one of FOUP, FOSB and SMIF.
